(19) United States
(12) Patent Application Publication
(10) Pub. No.: US 2018/0005851 A1
(43) Pub. Date: Jan. 4, 2018

(54) CHAMBER FILLER KIT FOR DIELECTRIC ETCH CHAMBER

(71) Applicant: Lam Research Corporation, Fremont, CA (US)

(72) Inventors: Benson Q. TONG, San Jose, CA (US); Harmeet SINGH, Fremont, CA (US); John HOLLAND, San Jose, CA (US); Ryan BISE, Los Gatos, CA (US)

(21) Appl. No.: 15/201,207

(22) Filed: Jul. 1, 2016

(51) Int. Cl. H01L 21/67; H01J 37/32; H01L 21/677

(52) U.S. Cl. CPC H01L 21/67069; H01L 21/67748; H01J 37/32009; H01J 37/32715; H01J 2237/334

(57) ABSTRACT

A chamber filler kit for balancing electric fields in a dielectric etch chamber is provided. A transport module filler comprises an electrical conductive body, an etch resistant surface, wherein the etch resistant surface comprises an inner curved surface, which matches a partial cylindrical bore of the etch chamber, and a wafer transport aperture, wherein the transport module filler fits into a transport aperture of the etch chamber. A transport module sealer plate is adapted to be mechanically and electrically connected to the partially cylindrical chamber body and the transport module filler. A bias housing filler is adapted to be mechanically and electrically connected to a bias housing wall and comprises a conductive body and an etch resistant surface, wherein the etch resistant surface comprises a curved surface, which matches the partial cylindrical bore.

### BACKGROUND

The present disclosure relates the production of semiconductor devices. More specifically, the present disclosure relates to the plasma processing of a substrate in the formation of semiconductor devices.

During semiconductor wafer processing, features may be etched into a dielectric layer.

### SUMMARY

To achieve the foregoing and in accordance with the purpose of the present disclosure, an embodiment provides a chamber filler kit for balancing electric fields in a dielectric etch chamber is provided, wherein the dielectric etch chamber comprises a partially cylindrical chamber body with a partial cylindrical bore with a transport aperture and a bias housing aperture opposite the transport aperture, and a bias housing wall adjacent to the bias housing aperture. A transport module filler comprises an electrical conductive body, an etch resistant surface, wherein the etch resistant surface comprises an inner curved surface, which matches the partial cylindrical bore, and a wafer transport aperture for allowing a wafer and a robotic arm to pass into the partial cylindrical bore, wherein the transport module filler fits into the transport aperture and fills at least half of a volume of the transport aperture. A transport module sealer plate is adapted to be mechanically and electrically connected to the partially cylindrical chamber body and the transport module filler and comprises a seal for creating a seal around the transport aperture. A bias housing filler is adapted to be mechanically and electrically connected to the bias housing wall and comprises a conductive body and an etch resistant surface, wherein the bias housing filler fills at least 75% of a volume of the bias housing aperture, and wherein the etch resistant surface comprises a curved surface, which matches the partial cylindrical bore.

In another manifestation, an embodiment provides chamber filler kit for balancing electric fields in a dielectric etch chamber, wherein the dielectric etch chamber comprises a partially cylindrical chamber body with a partial cylindrical bore with a transport aperture and a bias housing aperture and a bias housing wall adjacent to the bias housing aperture. A transport module filler comprises an electrical conductive body, an etch resistant surface, wherein the etch resistant surface comprises an inner curved surface, which matches the partial cylindrical bore, and a wafer transport aperture for allowing a wafer and a robotic arm to pass into the partial cylindrical bore, wherein the transport module filler fits into the transport aperture and fills at least half of a volume of the transport aperture. A bias housing filler is adapted to be mechanically and electrically connected to the bias housing wall. The bias housing filler comprises a conductive body and an etch resistant surface, wherein the bias housing filler fills at least 75% of a volume of the bias housing aperture, and wherein the etch resistant surface comprises a curved surface, which matches the partial cylindrical bore.

These and other features of the present disclosure will be described in more detail below in the detailed description of embodiments and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of a processing chamber used in an embodiment.

FIG. 2A is a perspective view of a chamber body.

FIG. 2B is a perspective view of a processing chamber with a top removed.

FIG. 3 is a top view of a substrate that has been processed in a chamber.

FIG. 4 is a schematic view of a processing chamber with an embodiment of a kit.

FIG. 5 is a perspective view of a processing chamber with a top removed and with an embodiment of a kit.

FIG. 6 is a more detailed perspective view of a bias housing filler.

FIG. 7 is a perspective view of a transport module sealer plate.

FIG. 8 is a perspective view of the transport module sealer plate with a transport module filler.

FIG. 9 is a top view of a substrate that has been processed in a chamber with a kit.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

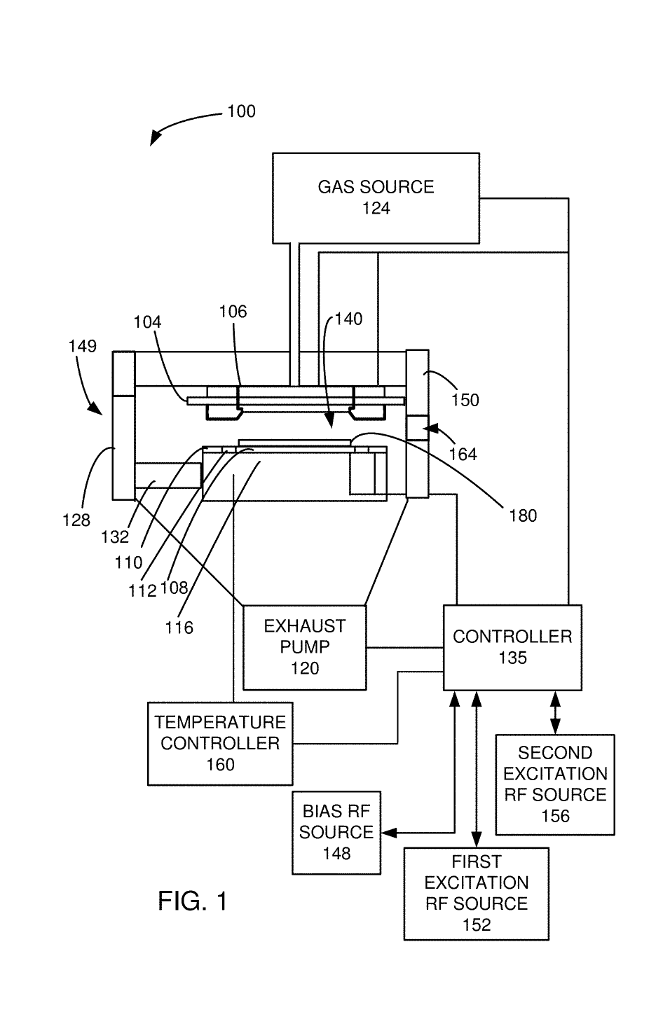

To facilitate understanding, FIG. 1 is a schematic cross sectional view of a plasma processing system 100 that may be used in an embodiment. In an embodiment, the plasma processing system 100 comprises a top central electrode 106, top outer electrode 104, bottom central electrode 108, and a bottom outer electrode 110, within a processing chamber 149, enclosed by a chamber body 150. A bottom insulator ring 112 insulates the bottom central electrode 108 from the bottom outer electrode 110. Also within the processing chamber 149, the substrate 180 is positioned on top of the bottom central electrode 108. The bottom central electrode 108 and forms part of an electrostatic chuck (ESC) and substrate support 116 for holding the substrate 180. In this embodiment the bottom outer electrode 110 and the top outer electrode 104 have apertures that have a larger diameter than the substrate 180, so that the substrate 180 is positioned within the apertures.

A gas source 124 is connected to the processing chamber 149 and supplies gas into a plasma region of the processing chamber 149 during the etch or open processes.

A bias RF source 148, a first excitation RF source 152, and a second excitation RF source 156 are electrically connected to the processing chamber 149 through a controller 135 to provide power to the electrodes 104, 106, 108, and 110. The bias RF source 148 generates bias RF power and supplies the bias RF power to the processing chamber 149. In this example, the bias RF power has a frequency of 2 MHz. The first excitation RF source 152 generates source RF power and supplies the source RF power to the processing chamber 149. In this example, this source RF power has a frequency of 27 MHz. The second excitation RF source 156 generates another source RF power and supplies the source RF power to the processing chamber 149, in addition to the RF power generated by the first excitation RF source 152. In this example, this source RF power has a frequency of 60 MHz. A temperature controller 160 is connected to control the temperature of the central electrode 108 forming the ESC.

The different RF signals may be supplied to various combinations of the top and bottom electrodes. Preferably, the lowest frequency of the RF should be applied through the bottom electrode on which the material being etched is placed, which in this example is the bottom central electrode 108. In this example, the top electrodes are grounded and power is only provided to the bottom central electrode 108.

The controller 135 is connected to the gas source 124, the temperature controller 160, the bias RF source 148, the exhaust pump 120, the first excitation RF source 152, and the second excitation RF source 156. The controller 135 controls the flow of the etch gas into the processing chamber 149, the chamber pressure, as well as the generation of the RF power from the three RF sources 148, 152, 156, the electrodes 104, 106, 108, and 110, and the exhaust pump 120.

The top central electrode 106 also serves as a gas distribution plate, which is connected to the gas source 124, and serves as a gas inlet for gas from the gas source 124. The exhaust pump 120 serves as a gas outlet removing gas, which passes from the top central electrode 106 through the plasma region to the exhaust pump 120. The exhaust pump 120 may help to control pressure.

A Flex FL® dielectric etch system made by Lam Research Corporation™ of Fremont, Calif. may be used in a preferred embodiment of the invention. In the Flex EX+ the upper electrodes are grounded.

The chamber body 150 has a bias housing aperture, which is sealed by a bias housing wall 128. A transport module aperture 164 is also formed into the housing wall 128, and is adapted to allow a wafer 180 to be transported into and out of the chamber body 150. The substrate support 116 is connected and supported by the bias housing wall 128 through a connector 132. The plasma processing system 100 is a variable gap system, where the connector 132 is able to move the substrate support 116 up or down, to vary the gap between the substrate support 116 and the top central electrode 106. Because the chamber body 150 has a bias housing aperture and the bias housing wall 128, which seals the bias housing aperture, is placed further from the substrate 180 than other parts of the chamber body 150. An asymmetric electrostatic field is applied at the substrate 180.

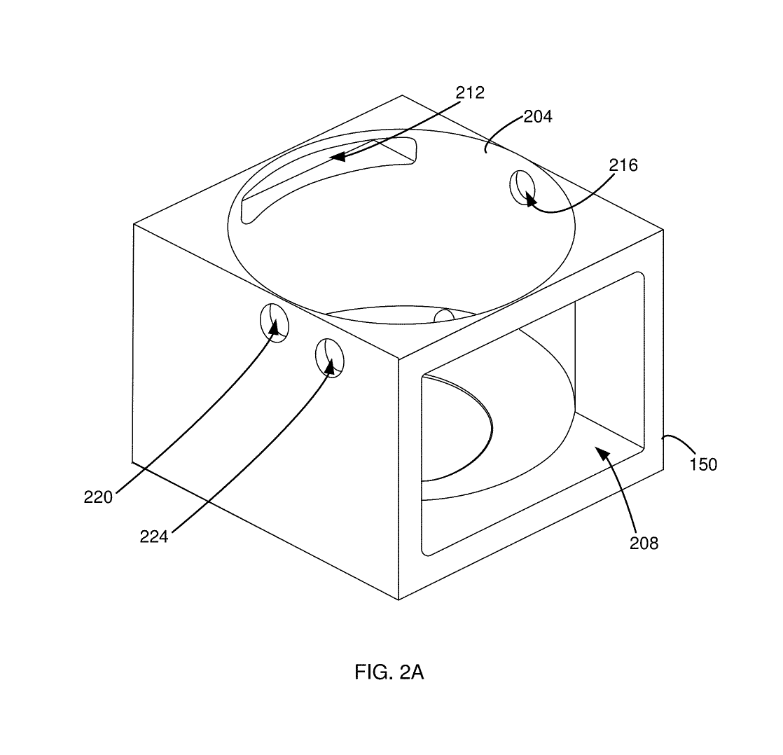

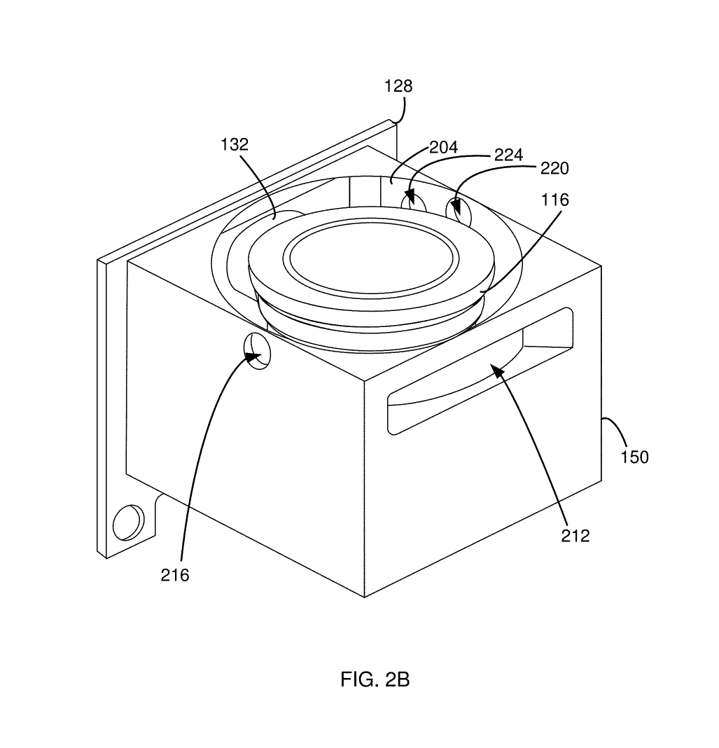

FIG. 2A is a perspective view of the chamber body 150. The chamber body 150 is a partially cylindrical chamber body in that the chamber body has a partial cylindrical bore forming a curved inner surface 204 forming a partial cylindrical bore, as shown. The bias housing aperture 208, a transport module aperture 164, a vent port 216, a view port 220, and an optical port 224 are formed into inner surface 204 causing the cylindrical bore to be incomplete. In this embodiment, the bias housing aperture 208 is opposite from the transport module aperture 164.

FIG. 2B is a perspective view of the chamber body 150, after being rotated and with the bias housing wall 128 attached, which covers and seals the bias housing aperture and with the top removed. The connector 132 connects the substrate support 116 to the bias housing wall 128.

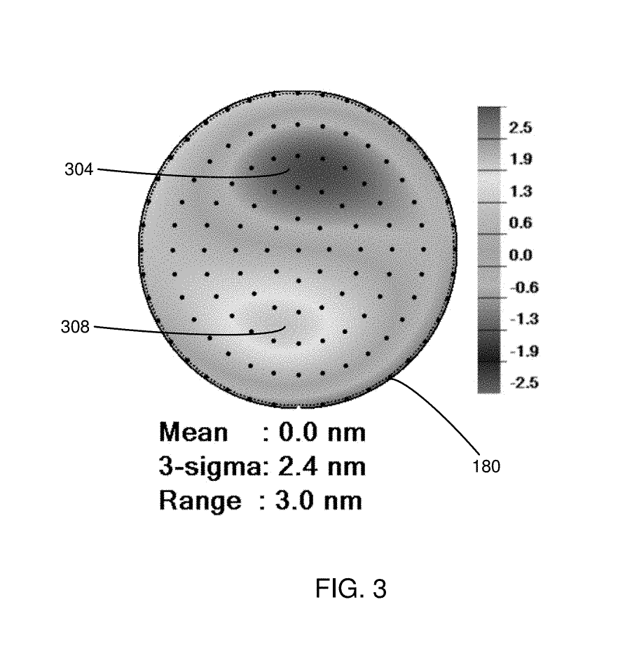

FIG. 3 is a schematic top view of a substrate 180 that has been processed in a chamber. A darker region 304 indicates a region lower than average etch rate. A lighter region 308 indicates a region with a higher than average etch rate. The range of etch depths is 3.0 nm, with a 3-sigma distribution of 2.4 nm. Under certain requirements, such an etch rate variation is unacceptable, because such a variance causes too many defects.

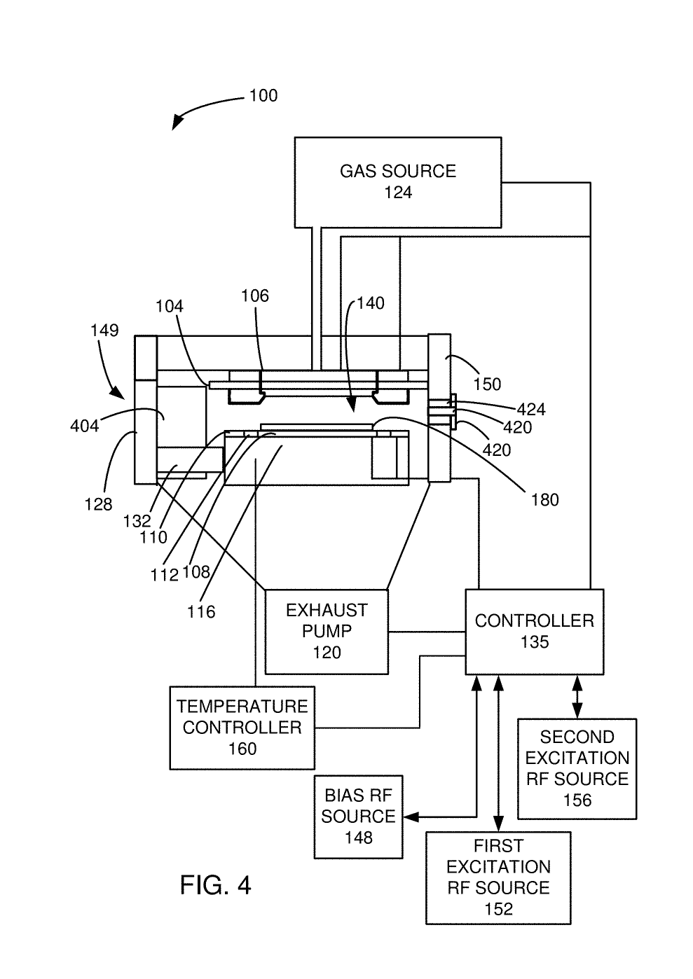

FIG. 4 is a schematic cross sectional view of the plasma processing system 100, configured according to an embodiment. A bias housing filler 404 is attached to the bias housing wall and fills the bias housing aperture. A transport module sealer plate 420 provides a seal around the transport module aperture and provided with a smaller aperture 422. A transport module filler 424 is attached to the transport module sealer plate 420 and fills at least part of the transport module aperture.

FIG. 5 is a perspective view of the chamber body 150 after an embodiment of the kit has been installed. A bias housing filler 508 is placed in the bias housing aperture. The bias housing filler 508 has an interior curved surface 512, which is flush with the curved inner surface 204 forming the partial cylindrical bore, so that the curved surface 512 helps to complete the cylindrical bore. The transport module sealer plate 420 provides a seal around the transport module aperture. A vent port filler 516 is placed in the vent hole. In this embodiment, the vent port filler 516 fills the entire cross-section of the vent hole, except for a single vent port filler bore 520 with a cross-sectional area of less than one fourth the cross-sectional area of the vent hole. Preferably, at least part of the vent port filler 516 is of a conductive material. A view port cover 524 is placed over the view port. As shown, the view port cover 524 comprises a conductive body with an etch resistant surface, and a plurality of view bores. Preferably, the total area of the view bores is less than one fourth of the cross-sectional area of the view port. Preferably, the view port cover 524 is curved to match the curved surface of the cylindrical bore. However, since the cross-sectional area of the view port is sufficiently small compared to the surface area of the cylindrical bore, a flat view port cover may be used in some embodiments. An optical port cover 528 is placed over the optical port. As shown, the optical port cover 528 comprises a conductive body with an etch resistant surface, and a plurality of optical bores. Preferably, the total area of the optical bores is less than one fourth of the cross-sectional area of the optical port. Preferably, the optical port cover 528 is curved to match the curved surface of the cylindrical bore. However, since the cross-sectional area of the optical port is sufficiently small compared to the surface area of the cylindrical bore, a flat optical port cover may be used in some embodiments.

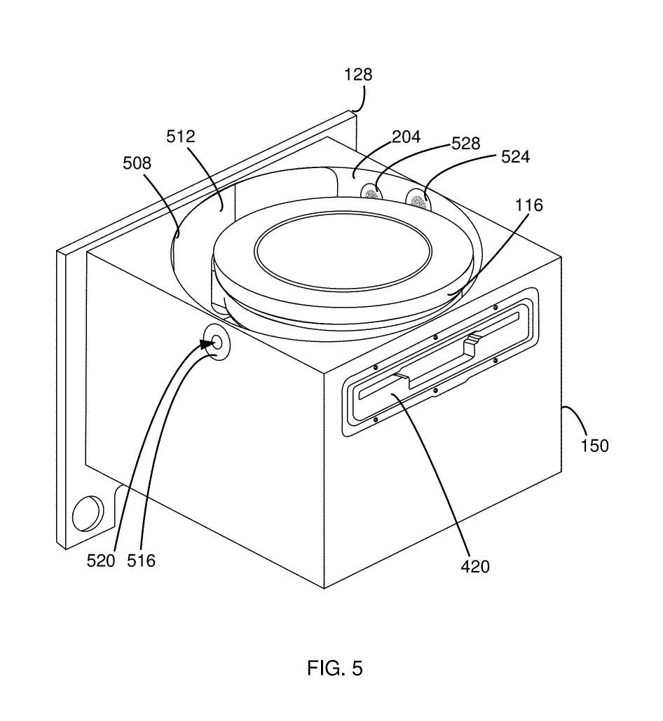

FIG. 6 is a more detailed view of the bias housing wall 128, the connector 132, and the substrate support 116 with the bias housing filler 508. In this embodiment, the bias housing filler is formed by two wedge shape parts with an interior curved surface 512, which is shaped to be flush with or match the curved inner surface 204 forming a partial cylindrical bore when mounted in the chamber 150, as shown in FIG. 5. In this embodiment, each wedge shaped part comprises a conductive body of aluminum with an etch resistant surface of anodized aluminum. In this example, the etch resistant surface forms the curved surface 512 and the remaining surface 516 the surface of the conductive body. In other embodiments, more of the surface of the conductor body is formed into an anodized aluminum etch resistant surface. Preferably, some of the surface is not anodized aluminum to allow the wedge shape part to be grounded to the bias housing wall 128. The volume of the bias housing filler is at least 75% of the volume of the bias housing aperture.

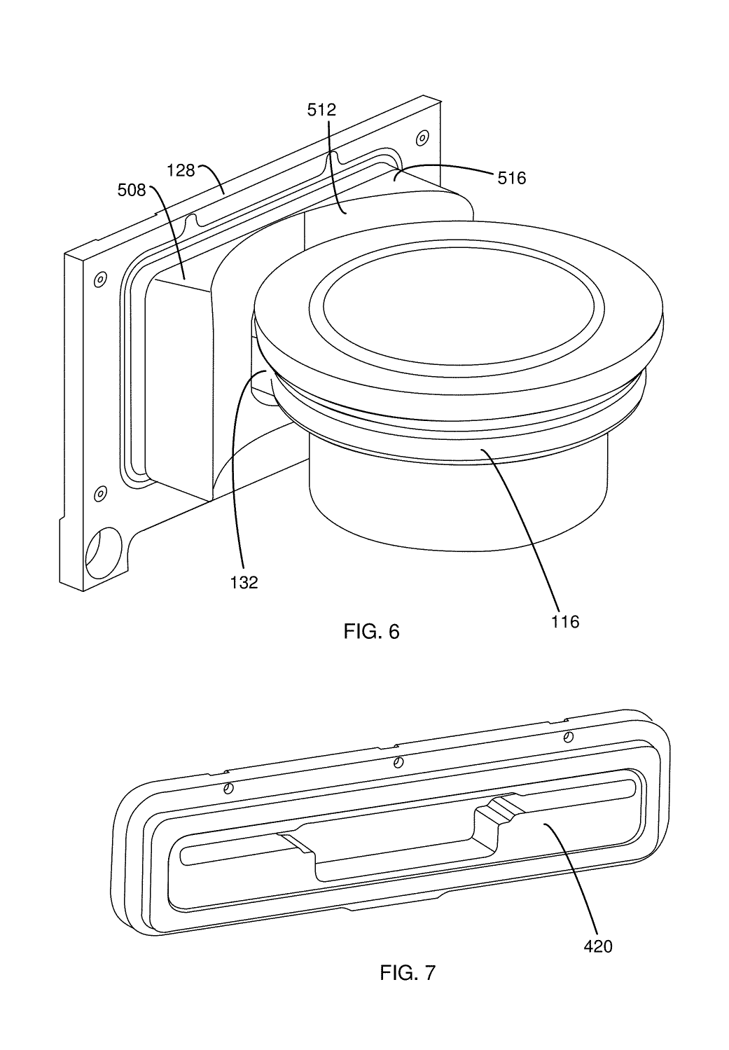

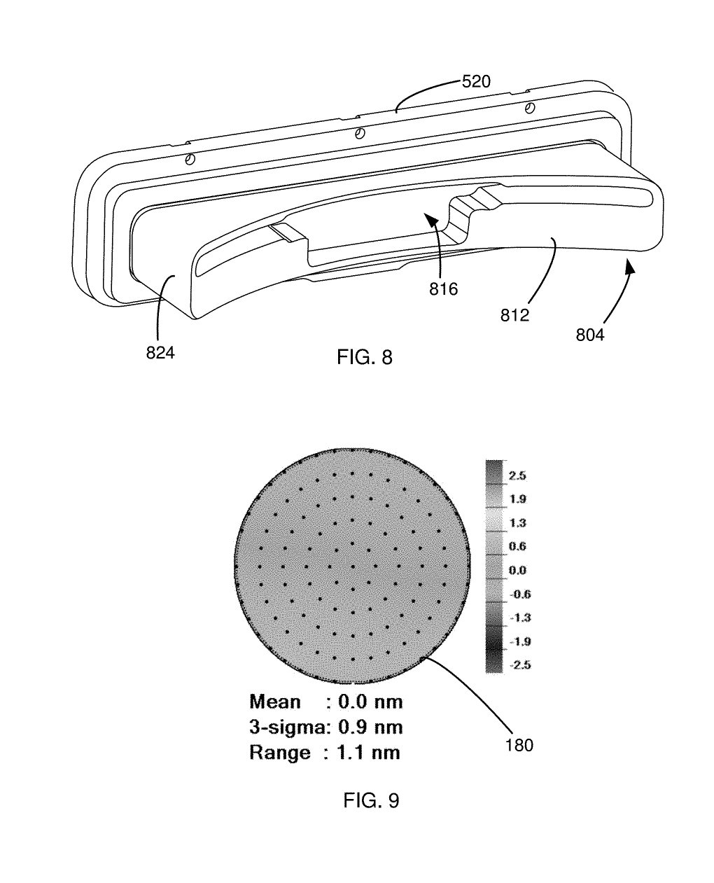

FIG. 7 is an enlarged perspective view of the transport module sealer plate 420. FIG. 8 is an enlarged perspective view of a transport module filler 804 connected to the transport module sealer plate 520. The transport module filler 804 comprises an electrically conductive body, which in this embodiment is aluminum, an etch resistant surface 812, and a wafer transport filler aperture 816. In this embodiment, the etch resistant surface 812 is part of a curved surface that matches the partial cylinder bore of the chamber. The etch resistant surface 812 may be anodized aluminum. Other surfaces 824 not exposed to plasma may be surfaces of the conductive body of the transport module filler 804. In other embodiments, more of the surface of the conductive body may be made etch resistant. Preferably, some part of the surface is a conductive surface of the conductive body to allow the conductive body to be grounded to either the transport module sealer plate 520 or the chamber body 150. The wafer transport filler aperture 816 has a volume that is less than half the volume of the transport module aperture. The wafer transport filler aperture 816 has a cross-sectional area sufficient to allow a wafer supported by a robotic arm to be passed into and out of the chamber 150.

FIG. 9 is a schematic top view of a substrate 180 that has been processed in a chamber that has been retrofitted according to an embodiment. The etching is more uniform across the substrate with a range of etch depths being 1.1 nm, with a 3-sigma distribution of 0.9 nm. Such a range and distribution has been found to be acceptable.

Without being bound by theory, it is believed that electrostatic asymmetries created by the apertures cause the uneven etching. These asymmetries created by the apertures also interfere with the gas flow, which may create additional uneven processing. It is believed that the retrofit kit being formed by a conductive material, similar to the chamber helps to correct electrostatic asymmetries created by the asymmetric chamber, which provides a more uniform result. It is also believed that the kit may improve physical symmetry, which may also provide a more uniform gas flow. The more uniform electrostatic field and gas flow provide a more uniform processing of the substrate.

Some embodiments allow for a grounded plasma. Various components are attached to the grounded sidewall. Various embodiments allow for the support to move the substrate support vertically to adjust the gap above the substrate support, providing a processing lever.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A chamber filler kit for balancing electric fields in a dielectric etch chamber, wherein the dielectric etch chamber comprises a partially cylindrical chamber body with a partial cylindrical bore with a transport aperture and a bias housing aperture opposite the transport aperture, and a bias housing wall adjacent to the bias housing aperture, the chamber filler kit comprising:
a transport module filler comprising:
an electrical conductive body;
an etch resistant surface, wherein the etch resistant surface comprises an inner curved surface, which matches the partial cylindrical bore; and
a wafer transport aperture for allowing a wafer and a robotic arm to pass into the partial cylindrical bore, wherein the transport module filler fits into the transport aperture and fills at least half of a volume of the transport aperture;
a transport module sealer plate adapted to be mechanically and electrically connected to the partially cylindrical chamber body and the transport module filler comprising a seal for creating a seal around the transport aperture; and
a bias housing filler adapted to be mechanically and electrically connected to the bias housing wall, comprising:
a conductive body; and
an etch resistant surface, wherein the bias housing filler fills at least 75% of a volume of the bias housing aperture, and wherein the etch resistant surface comprises a curved surface, which matches the partial cylindrical bore.

2. The chamber filler kit, as recited in claim 1, wherein the dielectric etch chamber further comprises a substrate support, which is mechanically connected to the bias housing wall, wherein the bias housing filler forms an aperture that at least partially surround a connection of the bias substrate support to the bias housing wall.

3. The chamber filler kit, as recited in claim 2, wherein the conductive bodies of the transport module filler and the bias housing filler comprise aluminum and the etch resistant surface of the bias housing filler and the transport module filler comprise anodized aluminum.

4. The chamber filler kit, as recited in claim 3, wherein the partially cylindrical chamber body further comprises a vent port, and wherein the chamber filler kit further comprises a vent port filler, wherein the vent port filler comprises:
a conductive body;
an etch resistant surface; and
a vent bore, wherein the vent bore has a cross-sectional area of less than one fourth of a cross-sectional area of the vent port.

5. The chamber filler kit, as recited in claim 4, wherein the partially cylindrical chamber body further comprises at least one view port, and wherein the chamber filler kit further comprises a view port cover, comprising:
a conductive body;
an etch resistant surface; and
a plurality of view bores, wherein a total area of the view bores has is less than one fourth of a cross-sectional area of the view port.

6. The chamber filler kit, as recited in claim 5, wherein the substrate support is movable, and wherein the aperture of the bias housing filler accommodates movement of the substrate support.

7. The chamber filler kit, as recited in claim 6, wherein the partially cylindrical chamber body further comprises at least one optical port, and wherein the chamber filler kit further comprises a optical port cover, comprising:
a conductive body;
an etch resistant surface; and
a plurality of view bores, wherein a total area of the view bores has is less than one fourth of a cross-sectional area of the optical port.

8. The chamber filler kit, as recited in claim 7, wherein the chamber filler kit provides a more symmetric gas flow through cylindrical chamber.

9. The chamber filler kit, as recited in claim 1, wherein the conductive bodies of the transport module filler and the bias housing filler comprise aluminum and the etch resistant surface of the bias housing filler and the transport module filler comprise anodized aluminum.

10. The chamber filler kit, as recited in claim 1, wherein the partially cylindrical chamber body further comprises a vent port, and wherein the chamber filler kit further comprises a vent port filler, wherein the vent port filler comprises:
a conductive body;
an etch resistant surface; and
a vent bore, wherein the vent bore has a cross-sectional area of less than one fourth of a cross-sectional area of the vent port.

11. The chamber filler kit, as recited in claim 1, wherein the partially cylindrical chamber body further comprises at least one view port, and wherein the chamber filler kit further comprises a view port cover, comprising:
a conductive body;
an etch resistant surface; and
a plurality of view bores, wherein a total area of the view bores has is less than one fourth of a cross-sectional area of the view port.

12. The chamber filler kit, as recited in claim 1, wherein the dielectric etch chamber further comprises a substrate support, which is mechanically connected to the bias housing wall, wherein the bias housing filler forms an aperture that at least partially surround a connection of the bias substrate support to the bias housing wall and wherein the substrate support is movable, and wherein the aperture of the bias housing filler accommodates movement of the substrate support.

13. The chamber filler kit, as recited in claim 1, wherein the partially cylindrical chamber body further comprises at least one optical port, and wherein the chamber filler kit further comprises a optical port cover, comprising:
a conductive body;
an etch resistant surface; and
a plurality of view bores, wherein a total area of the view bores has is less than one fourth of a cross-sectional area of the optical port.

14. The chamber filler kit, as recited in claim 1, wherein the chamber filler kit provides a more symmetric gas flow through cylindrical chamber.

15. The chamber filler kit, as recited in claim 1, wherein the conductive body of the bias housing filler comprises a comprises:
a first wedge shape part, wherein a surface of the first wedge shape part forms part of the curved surface of the bias housing filler; and
a second wedge shape part, wherein a surface of the second wedge shape part forms part of the curved surface of the bias housing filler,

16. A chamber filler kit for balancing electric fields in a dielectric etch chamber, wherein the dielectric etch chamber comprises a partially cylindrical chamber body with a partial cylindrical bore with a transport aperture and a bias housing aperture and a bias housing wall adjacent to the bias housing aperture, the chamber filler kit comprising:
a transport module filler comprising:
an electrical conductive body;
an etch resistant surface, wherein the etch resistant surface comprises an inner curved surface, which matches the partial cylindrical bore; and
a wafer transport aperture for allowing a wafer and a robotic arm to pass into the partial cylindrical bore, wherein the transport module filler fits into the transport aperture and fills at least half of a volume of the transport aperture; and
a bias housing filler adapted to be mechanically and electrically connected to the bias housing wall, comprising:
a conductive body; and
an etch resistant surface, wherein the bias housing filler fills at least 75% of a volume of the bias housing aperture, and wherein the etch resistant surface comprises a curved surface, which matches the partial cylindrical bore.

17. The chamber filler kit, as recited in claim 16, wherein the conductive bodies of the transport module filler and the bias housing filler comprise aluminum and the etch resistant surface of the bias housing filler and the transport module filler comprise anodized aluminum.
